(19) United States
(12) Patent Application Publication
(10) Pub. No.: US 2025/0068788 A1
(43) Pub. Date: Feb. 27, 2025

(54) METHOD FOR DETERMINING A TREATMENT SCHEDULE FOR TREATING AN AGRICULTURAL FIELD BASED ON THE MATCHING WITH THE FIELD POTENTIAL

(71) Applicant: BASF AGRO TRADEMARKS GMBH, Ludwigshafen (DE)

(72) Inventors: Stefan HANEBRINK, Koeln (DE); Karoline EPKE, Münster (DE); Bjoern KIEPE, Koeln (DE)

(21) Appl. No.: 18/723,169

(22) PCT Filed: Dec. 23, 2022
(86) PCT No.: PCT/EP2022/087697

§ 371 Date: Jun. 21, 2024

(30) Foreign Application Priority Data
Dec. 23, 2021 (EP) 21217246.4

(51) Int. Cl. G06F 30/20; G06Q 30/018; G06Q 50/02

(52) U.S. Cl. CPC G06F 30/20; G06Q 30/018; G06Q 50/02

(57) ABSTRACT

A method is provided, comprising providing crop data (10), (S20) proving field data (20), (S30) providing organism data (30), (S40) providing agricultural inputs data (40), (S50) providing field potential data (50), (S60) based on the crop data (10), field data (20), organism data (30), and agricultural inputs data (40), determining a set of treatment schedules for treating the agricultural field, (S70) determining the crop yield and the environmental impact associated with each treatment schedule within the determined set of treatment schedules, (S80) based on the field potential data (50), determining a field potential matching indicator for each treatment schedule within the determined set of treatment schedules using a matching model, (S90) selecting at least one treatment schedule based on the field potential matching indicator, (S100) based on the selected treatment schedule, outputting a control file usable for controlling an agricultural equipment which can be used to treat the agricultural field.

### FIELD OF THE INVENTION

The present invention relates to a computer-implemented method for determining a treatment schedule for treating an agricultural field based on the matching with the field potential, a system comprising units or means for carrying out such computer-implemented method, the use of the treatment schedule for controlling an agricultural equipment.

### BACKGROUND OF THE INVENTION

In practice, the farmer or user often faces the challenge that a treatment schedule is or will be automatically implemented on his/her agricultural field which does not necessarily match his/her field potential. For example, the field potential is that the further application of specific chemical crop protection products (e.g. a long-persisting herbicide) will lead to a high degree of retention and accumulation of this product in the soil and will ultimately lead to soil degradation, however, the treatment schedule determined for his field comprises the application of this specific crop protection product (e.g. a long-persisting herbicide). This may lead to the problem that the original treatment schedule is not best suited for this agricultural field, and another treatment schedule needs to be determined which might involve a longer waiting time, a higher process complexity and a lower degree of automation.

In view of the above problem and challenge, it was found that there is a need to improve and simplify the decision process of the farmer or user in view of the corresponding field potential.

### SUMMARY OF THE INVENTION

In view of the above, it is an object of the present invention to provide a method for determining optimal treatment schedules for treating an agricultural field based on the matching with the field potential, which can be easily applied by a farmer or user and which can be automized. It is also an object of the present invention to provide a computer-implemented method for determining optimal treatment schedules for treating an agricultural field, which supports fast and efficient decision-making for a farmer or user regarding the treatment of the agricultural field. It is also an object of the present invention to provide a computer-implemented method for determining optimal treatment schedules for treating an agricultural field, which does not need to undergo a further step of user approval or user check in view of the matching with the field potential. It is also an object of the present invention to provide a computer-implemented method to improve the control of harmful organisms in the agricultural field. It is also an object of the present invention to provide a computer-implemented method to improve the protection or usage of beneficial organisms—including the crop plants—in the agricultural field. It is also an object of the present invention to provide a computer-implemented method to improve the protection of the soil in the agricultural field.

The objects of the present invention are solved with the subject matter of the independent claims, wherein further embodiments are incorporated in the dependent claims. It should be noted that the following described aspects and examples of the invention apply for the method as well as for the system, the computer program product and the computer-readable storage medium.

According to the first aspect of the present invention, the present invention relates to a computer-implemented method for determining a treatment schedule for treating an agricultural field, the method comprising the steps:
a) (S10) providing crop data (10) being data relating to the at least one crop grown or planned to be grown in the agricultural field;
b) (S20) providing field data (20) being data relating to the field conditions, soil conditions, weather conditions and/or environmental conditions in the agricultural field,
c) (S30) providing organism data (30) being data relating to the actual or expected presence of an agriculturally relevant organism (Q) in the agricultural field and/or data relating to the actual or expected presence of health deficiencies of the organism (Q),
d) (S40) providing agricultural inputs data (40) being data relating to agricultural inputs usable for treating the agricultural field, wherein agricultural inputs comprise at least one of the following inputs: Seeds, irrigation water, fertilizer, chemical crop protection products, biological crop protection products, physical-mechanical crop protection products, agricultural equipment, and/or hours of manual labour work,
e) (S50) providing field potential data (50) relating to the field's potential regarding the treatment on the agricultural field,
f) (S60) based on the crop data (10), field data (20), organism data (30), and agricultural inputs data (40), determining a set of treatment schedules for treating the agricultural field, wherein the set of treatment schedules comprises at least two treatment schedules and wherein the treatment schedule comprises an indication to treat the agricultural field or to leave the agricultural field untreated and if the agricultural field is to be treated the treatment schedule comprises at least one treatment in an agricultural field for which a time window is indicated,
g) (S70) determining the crop yield and the environmental impact associated with each treatment schedule within the determined set of treatment schedules,
h) (S80) based on the field potential data (50), determining a field potential matching indicator for each treatment schedule within the determined set of treatment schedules using a matching model, wherein the matching model is at least dependent on the determined crop yield and/or the determined environmental impact associated with each treatment schedule,
i) (S90) selecting at least one treatment schedule based on the field potential matching indicator,
j) (S100) based on the selected treatment schedule, outputting a control file usable for controlling an agricultural equipment which can be used to treat the agricultural field; wherein the field potential data relate to the field's potential of achieving high crop yield or of achieving low environmental impact.

In an example the method also comprises providing product data and step f) additionally comprises determining the set of treatment schedules for treating the agricultural field based on the product data. Product data is also be used to assess the impact of agricultural input to determine good and/or optimal treatment schedules.

Product data may comprise the description of crop protection and fertilizer products as well as variety data. The description may include registration data and information about active ingredients in crop protection products, nutrient content of chemical or organic fertilizer, and/or product efficacy data. Information about active ingredients may comprise the active ingredient, a mode of action, actives, tox-classes, basic active ingredients (excluding salt, esther) and/or regional resistance information. Nutrient content of chemical or organic fertilizer may be classified as major-nutrients or micro-nutrients. Variety data may comprise registration, features and/or characteristics, recommendations about sowing density and/or sowing depth. Product data may be provided once per season and can be updated during the season, if adaption is required. Product data may comprise the properties and/or characteristics of a used product.

According to another preferred embodiment of the present invention, the set of treatment schedules comprises at least 3, preferably at least 5, more preferably at least 10, most preferably at least 20, particularly preferably at least 40, particularly at least 80 treatment schedules.

According to another preferred embodiment of the present invention, the step (S90) is carried out in a way that the treatment schedule having the highest field potential matching indicator is automatically selected.

According to another preferred embodiment of the present invention, the step (S60) is carried out in a way that the treatment schedule is determined using at least one of the following models: a crop model, a crop growth model, a pest prediction or pest distribution model, a weather model and/or an agronomic recommendation model.

According to another preferred embodiment of the present invention, the user is the person or the entity which is responsible for the farming and/or for conducting treatments in the agricultural field.

According to another preferred embodiment of the present invention, a minimum threshold for the field potential matching indicator is predefined, and—in case the field potential matching indicator determined in step (S80) has not exceeded the minimum threshold for any treatment schedule within the set of determined treatment schedules—the steps (S60), (S70), (S80) have to be repeated as many times as required until the determined field potential matching indicator has exceeded the minimum threshold for at least one treatment schedule, before the steps (S90) and (S100) are carried out.

According to another preferred embodiment of the present invention, the agriculturally relevant organism (Q) is a harmful organism (HQ) selected from the group consisting of weeds, fungi, viruses, bacteria, insects, arachnids, nematodes, mollusks, and rodents.

According to another preferred embodiment of the present invention, the agriculturally relevant organism (Q) is a beneficial organism (BQ) selected from the group consisting of beneficial plants including but not limited to the crop plant as such, beneficial weeds, beneficial viruses, beneficial bacteria, beneficial insects including but not limited to pollinators, beneficial arachnids, beneficial nematodes, beneficial mollusks, and protozoa. According to another preferred embodiment of the present invention, the agriculturally relevant organism (Q) is the crop plant as such, which more preferably shows a health deficiency, particularly a nutrient deficiency.

According to another preferred embodiment of the present invention, the field data comprise historic treatment data (22) relating to the parameters or efficacies of treatments occurring or planned in the past. In an example the field data comprise historic treatment data (22) relating to legal restrictions and the parameters or efficacies of treatments occurring or planned in the past.

According to another preferred embodiment of the present invention, the field potential data are in-season data and/or pre-season data.

In-season data are data that are gathered with a frequency of equal or higher than once per year, e.g. data that are gathered once every 3 months.

Pre-season data are data that are gathered with a frequency of equal or lower than once per year, e.g. every March of a year.

According to another preferred embodiment of the present invention, wherein the field potential data relates to the field's potential to provide a habitat for to-be-protected animals or plants or for pollinators.

According to another preferred embodiment of the present invention, the treatment schedule comprises seeding and/or the use of specific seeds.

According to another preferred embodiment of the present invention, the treatment schedule comprises the application of fertilizers.

According to another preferred embodiment of the present invention, the treatment schedule comprises the application of chemical crop protection products.

According to another preferred embodiment of the present invention, the treatment schedule does not comprise the application of chemical crop protection products.

According to another preferred embodiment of the present invention, in case the field potential matching indicator is equal or comparable for at least two treatment schedules, the selection in step (S90) between these at least two treatment schedules is made either based on the crop yield and/or based on the environmental impact of these at least two treatment schedules.

The field potential matching indicator can be represented as a numeric value, a numeric range, a color code, a vector, a matrix, a barcode, a QR code, or an identifier.

According to a second aspect of the present invention, the present invention relates to a system for determining a treatment schedule for treating an agricultural field, comprising
1) a crop data provider (100) configured to provide crop data (10) being data relating to the at least one crop grown or planned to be grown in the agricultural field;
2) a field data provider (200) configured to provide field data (20) being data relating to the field conditions, soil conditions, weather conditions and/or environmental conditions in the agricultural field;
3) an organism data provider (300) configured to provide organism data (30) being data relating to the actual or expected presence of an agriculturally relevant organism (Q) in the agricultural field and/or data relating to the actual or expected presence of health deficiencies of the organism (Q),
4) an agricultural inputs data provider (400) configured to provide agricultural inputs data (40) being data relating to agricultural inputs usable for treating the agricultural field, wherein agricultural inputs comprise at least one of the following inputs: Seeds, irrigation water, fertilizer, chemical crop protection products, biological crop protection products, physical-mechanical crop protection products, agricultural equipment, and/or hours of manual labour work,
5) a field potential data provider (500) providing field potential data (50) relating to the field's potential regarding the treatment on the agricultural field,
6) a treatment schedule generator (600) configured to determine—based on the crop data (10), field data (20), organism data (30), and agricultural inputs data (40)—a set of treatment schedules for treating the agricultural field, wherein the set of treatment schedules comprises at least two treatment schedules,
7) a crop yield or environmental impact generator (700) configured to determine the crop yield and the environmental impact associated with each treatment schedule within the determined set of treatment schedules,
8) an indicator generator (800) configured to determine—based on the field potential data (40)—a field potential matching indicator for each treatment schedule within the determined set of treatment schedules using a matching model, wherein the matching model is at least dependent on the determined crop yield and/or the determined environmental impact associated with each treatment schedule,
9) a treatment schedule selector (900) configured to select the treatment schedule based on the field potential matching indicator,
10) an outputting unit (1000) configured to output—based on the selected treatment schedule—a control file usable for controlling an agricultural equipment which can be used to treat the agricultural field.

In an example the system also comprises a product data provider configured to provide product data and the treatment schedule generator is further configured to determining the set of treatment schedules for treating the agricultural field based on the product data. Product data is also be used to assess the impact of agricultural input to determine good and/or optimal treatment schedules. Product data may comprise registration data and/or product efficacy data. Product data may be provided once per season and can be updated during the season, if adaption is required. Product data may comprise the properties and/or characteristics of a used product.

According to a third aspect of the present invention, the present invention relates to a computer program product for determining a treatment schedule for treating an agricultural field, wherein the computer program product comprises instructions, which when executed perform the computer-implemented method of the present invention.

According to a fourth aspect of the present invention, the present invention relates to a computer-readable storage medium comprising instructions which, when executed by a computer, cause the computer to carry out the computer-implemented method of the present invention.

According to a fifth aspect of the present invention, the present invention relates to the use of a treatment schedule determined according to the methods of the present invention for controlling an agricultural equipment for treating an agricultural field.

In another preferred embodiment of the present invention, the agricultural equipment is preferably one of the following: a seeding equipment, a fertilizing equipment, a conventional sprayer, a smart sprayer, an autonomous application robot or an unmanned aerial vehicle.

According to a further preferred embodiment of the present invention, data relating to the weather conditions in the agricultural field (as included in the field data) include but are not limited to data relating to temperature, soil temperature, canopy temperature, humidity, precipitation, moisture, wind conditions, wind speed, wind direction, sunlight levels etc.

According to a further preferred embodiment of the present invention, data relating to the field conditions in the agricultural field (as included in the field data) include but are not limited to GPS (Global Positioning System) data, elevation data, topography data etc.

According to a further preferred embodiment of the present invention, data relating to the soil conditions in the agricultural field (as included in the field data) include but are not limited to data relating to soil texture, soil quality, soil moisture, soil sandiness, soil density, soil conductivity, soil pH value, nutrient composition of the soil, nitrogen content of the soil, potassium content of the soil, phosphorus content of the soil, sulfur content of the soil, calcium content of the soil etc.

According to a further preferred embodiment of the present invention, data relating to the environmental conditions in the agricultural field (as included in the field data) include but are not limited to data relating to biodiversity, to buffer zones, to the presence of to-be-protected animals or plants or its habitats, to the air quality or to the water quality.

According to a further preferred embodiment of the present invention, the crop data, the field data, the organism data and/or the agricultural inputs data have been provided by a user interface and/or by a data interface. According to a further preferred embodiment of the present invention, the crop data, the field data, the organism data, and/or the agricultural inputs data have been provided as a direct or indirect sensor measurements, preferably as real-time sensor measurements, more preferably as (real-time) sensor measurements via remote sensing, drone imagery, cameras etc.

According to a further preferred embodiment of the present invention, the field potential data have been provided by a user interface and/or by a data interface, preferably by a data interface to a farm management system, or to a field management system.

According to a further preferred embodiment of the present invention, the field potential data have been provided as a direct or indirect sensor measurements, preferably as real-time sensor measurements, more preferably as (real-time) sensor measurements via remote sensing, drone imagery, cameras etc.

According to a further preferred embodiment of the present invention, the timeframe between step (S10) and step (S90) is from 1 seconds to 5 days, more preferably from 1 minute to 3 days, most preferably from 1 minute to 1 day, particularly preferably from 1 minute to 10 hours, particularly more preferably from 1 minute to 5 hours, particularly from 1 minute to 1 hour, for example from 1 minute to 5 minutes.

According to a further preferred embodiment of the present invention, the steps (S10) to (S90) are carried out in a real-time mode, i.e. preferably less than a minute, more preferably within 10 to 45 seconds, most preferably within 1 to 10 seconds, more preferably within 0.5 to 1 seconds, most preferably within 100 to 500 milliseconds, particularly within 10 to 100 milliseconds.

According to a further preferred embodiment of the present invention, the step (S70) is carried out using crop yield models for the determination of the crop yields.

According to a further preferred embodiment of the present invention, a chemical crop protection product is a product selected from the group consisting of herbicide, fungicide, insecticide, acaricide, molluscicide, nematicide, rodenticide, repellant, bactericide, biocide, safener, adjuvant, plant growth regulator, urease inhibitor, nitrification inhibitor, or denitrification inhibitor, or any combination thereof.

According to a further preferred embodiment of the present invention, a biological crop protection product is a product selected from the group consisting of bioherbicide, biofungicide, bioinsecticide, bioacaricide, biomolluscicide, bionematicide, biological rodenticide, biological repellant, biological bactericide, biological biocide, biological safener, biological adjuvant, biological plant growth regulator, biological urease inhibitor, biological nitrification inhibitor, or biological denitrification inhibitor, or any combination thereof, or any microorganism having the function of a herbicide, fungicide, insecticide, acaricide, molluscicide, nematicide, rodenticide, repellant, bactericide, biocide, safener, adjuvant, plant growth regulator, urease inhibitor, nitrification inhibitor, or denitrification inhibitor.

According to a further preferred embodiment of the present invention, a physical-mechanical crop protection product is a product selected from the group consisting of optical crop protection tools (e.g. laser guns), physical crop protection tools (e.g. fire burner for weed removal), and mechanical crop protection tools (e.g. weed-cutting robots).

### Definitions

In the context of the present invention, the term “organism” is understood to be any kind of individual entities having the properties of life, including but not limited to plants, crop plants, weeds, fungi, viruses, bacteria, insects, arachnids, nematodes, mollusks, rodents, other animals, protozoa, protists, and archaea.

In the context of the present invention, the term “yield” is understood to be the harvested plant or crop biomass (e.g., indicated in tons or kilograms) per area unit (e.g., indicated in hectare or square meters) and per vegetation period (e.g., season), and yield is indicated for example as tons per hectare or kilograms per hectare. Notably, the term “yield” in the present disclosure can mean both, the so called “biological yield” and the so called “economic yield”. Preferably, “yield” means the biological yield. The “biological yield” is defined as “the total plant mass, including roots (biomass), produced per unit area and per growing season”. For the “economic yield”, “only those plant organs or constituents” are taken into account “around which the plant is grown”, wherein “a high biological yield is the basis for a high economic yield” (see Hans Mohr, Peter Schopfer, Lehrbuch der Pflanzenphysiologie, 3rd edition, Berlin/Heidelberg 1978, p. 560-561).

In the context of the present invention, the term “environmental impact” is understood to be any kind of impact on the environment, including but not limited to air pollution, water pollution, soil pollution, adverse effects on biodiversity, adverse effects on beneficial organisms such as pollinators, emission of environment-relevant substances, carbon footprint, water footprint, etc. Low environmental impact means high sustainability, while high environmental impact means low sustainability. Typically, the use of chemical crop protection products has a higher environmental impact compared with the use of biological crop protection products or physical-mechanical crop protection products (e.g., weed-cutting robots).

In the context of the present invention, the term “field potential” is understood to be the potential of an agricultural field to accept the specific treatment or treatment schedule, i.e., the compatibility of a specific treatment or treatment schedule with the agricultural field. The “field potential” has to be assessed in a holistic view considering all aspects of an individual agricultural field, including but not limited to soil properties (e.g. soil texture, soil quality, nutrient content in the soil etc.), water availability, historic treatments (including crops grown in the past, soil treatments, application of crop protection products or fertilizers) carried out in this agricultural field, historic yield potential of this agricultural field, biodiversity, presence of to-be-protected animals or plants in the agricultural field or in its vicinity, adverse effects potentially caused by climate change.

In the context of the present invention, the term “treatment” is understood to be any kind of treatment possible in an agricultural field, including but not limited to seeding, fertilization, crop protection, growth regulation, harvesting, adding or removing of organisms—particularly crop plants—, as well as soil treatment, soil nutrient management, soil nitrogen management, tilling, ploughing, irrigation. In a preferred embodiment of the present invention, treatment is one of the following activities: seeding, fertilization, crop protection, growth regulation, harvesting, adding or removing of organisms—particularly crop plants—, as well as soil treatment, soil nutrient management, soil nitrogen management, tilling, ploughing, irrigation. In another preferred embodiment of the present invention, treatment is seeding. In another preferred embodiment of the present invention, treatment is fertilization. In another preferred embodiment of the present invention, treatment is crop protection. In another preferred embodiment of the present invention, treatment is growth regulation. In another preferred embodiment of the present invention, treatment is harvesting. In another preferred embodiment of the present invention, treatment is adding or removing of organisms—particularly crop plants.

In the context of the present invention, the term “treatment schedule” is understood to be a schedule comprising at least one treatment for which a time window is indicated. In an example, the treatment schedule indicates at least one of the time, the product and the way of treatment.

In a further example the treatment schedule may comprise the decision to treat the agricultural field or not. A sustainable treatment schedule may comprise the decision to leave the agricultural field untreated. Preferably, a treatment schedule may also include seeding rates of seeds and/or dose rates of a crop protection product. Preferably, a treatment schedule may also include an application map or an indication where to treat within an application map. Typically, if the treatment schedule is determined before the crop plant has been sown or grown (i.e., before the season and/or pre-seasonal), the treatment schedule comprises preferably at least two, more preferably at least three, most preferably at least four, particularly at least five treatments (e.g., seeding of the crop plant, and applying a fertilizer and/or applying a crop protection product) for which a time window is indicated. Typically, if the treatment schedule is determined after the crop plant has been sown or grown (i.e., during the season and/or in-seasonal), the treatment schedule comprises fewer treatments, preferably comprises at least one treatment, and more preferably comprises at least two treatments (e.g., applying a fertilizer and/or applying a crop protection product) for which a time window is indicated. In an example, after the treatment has been conducted, the selected treatment schedule maybe reviewed, also under the aspect whether the time windows were appropriate.

In the context of the present invention, the term “agricultural field” is understood to be any area in which organisms, particularly crop plants, are produced, grown, sown, and/or planned to be produced, grown or sown. The term “agricultural field” also includes horticultural fields, silvicultural fields and fields for the production and/or growth of aquatic organisms.

In the context of the present invention, the term “control file” is any binary file, data, signal, identifier, information, or application map useful for controlling a treatment system usable for treating the agricultural field. In a further preferred embodiment of the present invention, the control file is an application map.

In the context of the present invention, the term “dose rate” is understood as amount of product to be applied per area, for example expressed as liter per hectare (L/ha).

In the context of the present invention, the time window for a treatment can preferably range from 10 days to 1 hour, more preferably from 7 days to 3 hours, most preferably from 5 days to 5 hours, particularly preferably from 3 days to 8 hours, particularly more preferably from 2 days to 12 hours, particularly from 36 hours to 16 hours, for example from 28 hours to 20 hours. In an example the time window may indicate a time interval during which a treatment and/or action may be necessary from the point in time of making the decision about the treatment schedule.

The time window may indicate that a treatment may have to be conducted within a time interval of 3 days. The time window may also indicate that a treatment may have to be conducted within a time interval of 1 hour. The time window may depend on an environmental property such as a weather forecast.

In the context of the present invention, the term “application map” is understood to be a map indicating a two-dimensional spatial distribution of the amounts, or dose rates, or types, or forms of products which should be applied on different locations or zones within an agricultural field. In the context of the present invention, the term “zone” or “sub-field zone” is understood to be a zone or a part of an agricultural field, i.e., an agricultural field can be spatially divided into more than one zone, wherein each zone may have different properties such as different biomass levels or different weed and/or pathogen infestation risks. Particularly, the application map may indicate that in different zones, different amounts, or dose rates, or types, or forms of products should be applied. For example, the application map may indicate that in the first zone, the product should be applied in a product dose rate of 10 litres per hectare, and in the second zone, the same product should be applied in a product dose rate of 20 litres per hectare.

The steps (S10), (S20), (S30), (S40), (S50) does not have to be carried out in a specific order. These five steps can be carried out in any thinkable order, or can be also carried out completely or partially simultaneously.

### Model Details

In a preferred embodiment of the present invention, the matching model for example works as follows:
In case it can be derived from the field potential data that the field can potentially accept a high degree of environmental impact, treatment schedules having a higher crop yield will be assigned a higher field potential matching indicator,
In case it can be derived from the field potential data that the field cannot potentially accept a high degree of environmental impact (e.g., because a high amount of agrochemicals have already been accumulated on this agricultural field, or because the field is also the habitat for a to-be-protected animal species), treatment schedules having a lower environmental impact will be assigned a higher field potential matching indicator,
In case it can be derived from the field potential data that the field has a great potential for sustainable farming or organic farming (e.g., because the soil needs to get recovery after being accumulated with chemical crop protection products), all treatment schedules in which the use of chemical crop protection products is required will be assigned a lower field potential matching indicator,
In case it can be derived from the field potential data that many pollinators are active or present in this field, all treatment schedules in which the use of chemical crop protection products which are dangerous or toxic for pollinators is required will be assigned a lower field potential matching indicator.

### DESCRIPTION OF THE DRAWINGS

FIG. 1

FIG. 1 illustrates the workflow of the present invention: In step (S10), crop data being data relating to the at least one crop grown or planned to be grown in the agricultural field are provided.

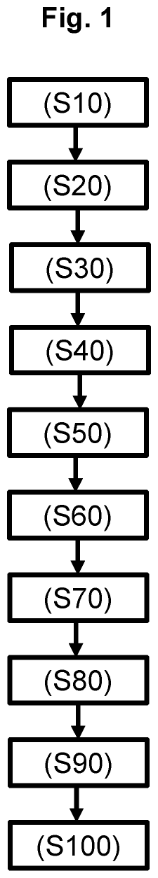

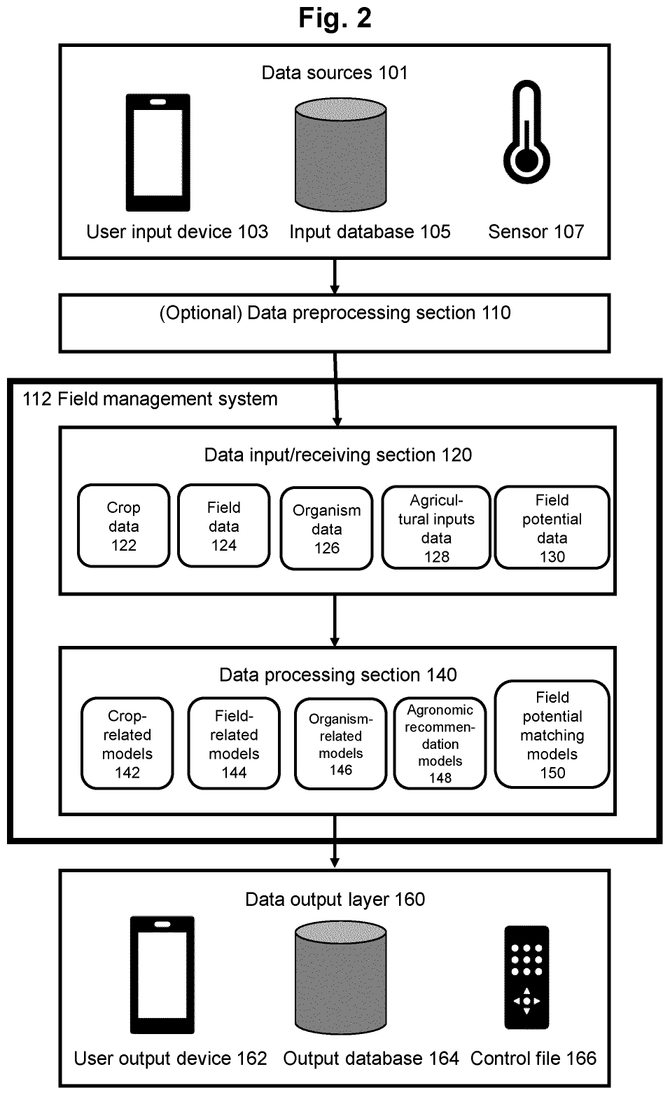

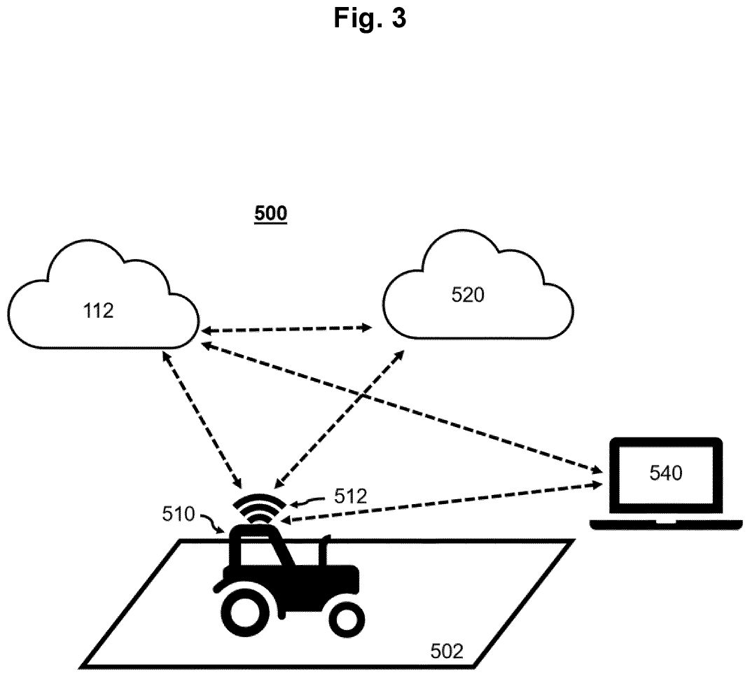

In step (S20), field data being data relating to the field conditions, soil conditions, weather conditions and/or environmental conditions in the agricultural field are provided. In step (S30), organism data (30) being data relating to the actual or expected presence of an agriculturally relevant organism (Q) in the agricultural field and/or data relating to the actual or expected presence of health deficiencies of the organism (Q) are provided. In step (S40), agricultural inputs data (40) being data relating to agricultural inputs usable for treating the agricultural field are provided. In step (S50), field potential data (50) are provided. In step (S60), a set of treatment schedules for treating the agricultural field is determined based on the crop data (10), field data (20), organism data (30), and agricultural inputs data (40), wherein the set of treatment schedules comprises at least two treatment schedules. In step (S70) determining the crop yield and the environmental impact associated with each treatment schedule within the determined set of treatment schedules are determined. In step (S80), based on the field potential data (50), a field potential matching indicator is determined for each treatment schedule within the determined set of treatment schedules using a matching model, wherein the matching model is at least dependent on the determined crop yield and/or the determined environmental impact associated with each treatment schedule. In step (S90), at least one treatment schedule is selected based on the field potential matching indicator. In step (S100), a control file usable for controlling an agricultural equipment, which can be used to treat the agricultural field, is outputted based on the selected treatment schedule.

Crop data are data that describe the crop. Crop data may comprise the crop type, e.g. winter wheat and/or variety e.g. Chevignon.

Other crop data may comprise in season monitoring data such as start of vegetation period, yield forecast, phenology—current growth stage, phenology for example predicted BBCH 61, predicted BBCH 69, predicted BBCH 89, and/or crop drought stress. The BBCH scale (Biologische Bundesanstalt für Land-und Forstwirtschaft, Bundessortenamt und CHemische Industrie) is an example used to classify the growth stage of plants.

Crop data may also comprise the susceptibility for a harm described by the EPPO code (European and Mediterranean Plant Protection Organization) such as PYRNTR (Pyrenophora tritici repentis) susceptibility, GIBBZE (Fusarium graminearum) susceptibility, PUCCSI (Puccinia striiformis f. sp. tritici) susceptibility, SEPTTR (Zymoseptoria tritici) susceptibility, PSDCHE (Oculimacula yallundae) susceptibility, ERYSGT (Blumeria graminis f. sp. tritici) susceptibility, PUCCRT (Puccinia triticina) susceptibility. In another example crop data may also comprise lodging of the variety and their assessment like medium, above medium, low, below medium, very low etc.

Field data describe the location of the field and may provide parameter like country where the field is located, geolocation, political region, altitude, soil-climate-region, soil, water body distance, Exposition, windopen location, crop which may link to the crop data, e.g. winter wheat, variety name which may also link to the crop data, seeding date, sowing density, sowing depth, tillage, cultivation system, previous crop, yield expectation, crop usage such as grain, weather data, soil water content such as dry, frost risk e.g. yes or no, spray weather conditions, disease observations.

Field data may comprise field yield potential and sustainability potential. The field yield potential is a characteristic of the field and may provide a prediction how much yield may be expected from the field. The sustainability potential may indicate how well the field fits to sustainable treatment methods.

Organism data may comprise data regarding disease development based on weather data e.g., current infection conditions, infection conditions since seeding amount of infections still in incubation, infection predicted and risk assessment of e.g., SEPTTR, PUCCSI, PSDCHE, ERYSGR, PUCCRT.

Organism data may also comprise an assessment about preseason initial disease risk, historical infection risk analysis, monitoring and trial data of e.g., GIBBZE, PYRNTR, SEPTTR, PUCCSI, PSDCHE, ERYSGR, PUCCRT. The assessment may result in values such as false and true or individual categorization like medium, low, high.

Organism data may further comprise the presence of e.g., beneficial insects, the presence of flowering plants, the presence of field margins and the presence of bee houses.

In a preferred embodiment of the present invention, the field potential may be defined by a plurality of field potential data. The field potential data may indicate different characteristics for the field potential and may describe a vector in a solution space. The field potential data may comprise field yield potential data, field risk potential data and/or field sustainability potential data.

In a preferred embodiment of the present invention, the field potential may be expressed by field potential data. The field potential data may be calculated from field yield potential data, field risk potential data and/or a sustainability potential data.

According to step h) a field potential matching indicator is determined for each treatment schedule within the determined set of treatment schedules based on the field potential data (50). For determining the field potential matching indicator, a matching model is used. The matching model is dependent on the determined crop yield and/or the determined environmental impact associated with each treatment schedule.

The field potential data may be the sum of the field yield potential data and field risk potential data and/or sustainability potential. The field potential data may be calculated pre-seasonable or once a year, preferably before the treatment start.

In parallel to the field potential data, the set of treatment schedules for treating the agricultural field is selected. The treatment schedule is selected based on a treatment strategy, e.g., a ROI (Return on Investment), a sustainability and/or a yield strategy. The ROI strategy tries may be to keep the effort made for growing a crop low and ROI strategy may consider targeted product selection, reduction of passages and/or consideration of yield prediction. The sustainability strategy tries to keep the TFI (Treatment Frequency Index) low, for example by adapting the dose rate, by targeted product selection based on the field potential etc. The yield strategy may try to reach a high yield, e.g., by extensive disease control, applying of premium product, by taking safety measures etc.

A minimum field potential matching indicator and/or a minimum field potential value is allocated to each treatment schedule that may indicate what minimum field potential data is need in order to select the specific schedule under the condition of a certain treatment strategy.

The different field potential data may be matched with corresponding field potential indicator of the set of treatment schedules. The field potential matching indicator is calculated for each treatment schedule. The treatment schedules may be based on crop data (10), field data (20), organism data (30) and agricultural input data (40) wherein those data differ from the selected crop data, field data, organism data and agricultural input data that are used for calculating the field potential.

In other words, the treatment schedules and the field potential data are determined independently from another. Each treatment schedule of the determined set of treatment schedules is examined based on the field yield potential data, field risk potential data and/or field sustainability potential data. Derived from these data, a potential field potential value for the field may be calculated.

Thus, if the set of treatment schedules comprises two treatment schedules, the first treatment schedule gets a first field yield potential matching factor, a first field risk potential matching factor and/or a first field sustainability potential matching factor, based on at least one of these factors, the field potential matching indicator for the first treatment schedule may be calculated.

The second treatment schedule gets a second field yield potential matching factor, a second field risk potential matching factor and/or a second field sustainability potential matching factor, based on at least one of these factors, the field potential matching indicator for the second treatment schedule may be calculated.

The matching factors may indicate how well the corresponding treatment schedules match field potential data which are derived from the field properties. The field properties may comprise field yield potential data, field risk potential data and/or a field sustainability potential data.

These data may be combined to field potential data for the field.

The first treatment schedule may have first field yield potential points, first field risk potential points and/or first field sustainability potential points.

The second treatment schedule may have second field yield potential points, second field risk potential points and/or second field sustainability potential points.

Those field potential points are matched with the field potential data and the best match may be selected.

The field potential data that are used for field potential assessment of the field are substantially pre-seasonally determined.

Field potential data comprise field yield potential. Field yield potential data are a sub-group of field data.

Field yield potential data may indicate a high efficiency of a field.

Field yield potential data comprise immutable data and data that are recorded substantially once per season. The immutable field data may comprise a soil value number. The field data recorded once per season may comprise power zones analysis, absolute biomass map analysis values and yield map analysis values.

The field risk potential data may be based on field data, agricultural input data and organism data. The field risk potential may comprise substantially immutable field data, e.g., long-term accumulated precipitation. The field risk potential may also comprise field data recorded once per season, e.g. CEPI (Cluster für die regionale Erhebung und Analyse der Pflanzenschutzinten-sität) FUN (Fungicide) treatment index, PAPA JKI (Panel Pflanzenschutzmittel-Anwendung, Julius Kuhn Institut) FUN treatment index, regional crop intensity and/or Frequency of crop in rotation history (field and farm).

The field risk potential may also comprise agricultural input data recorded once per season, e.g., seed treatment and/or organic fertilizer.

The field risk potential data may be high when a long history of extensive treatment of the field exists. A high risk factor may reduce the yield potential.

In addition the field risk potential may also comprise organism data recorded once per season, e.g. GIBBZE preseason initial disease risk, PYRNTR preseason initial disease risk, SEPTTR preseason initial disease risk, PUCCSI preseason initial disease risk, PSDCHE preseason initial disease risk, ERYSGR preseason initial disease risk, PUCCRT preseason initial disease risk, GIBBZE historical infection risk analysis, PYRNTR historical infection risk analysis, SEPTTR historical infection risk analysis, PUCCSI historical infection risk analysis, PSDCHE historical infection risk analysis, ERYSGR historical infection risk analysis, PUCCRT historical infection risk analysis, GIBBZE monitoring and trial data, PYRNTR monitoring and trial data, SEPTTR monitoring and trial data, PUCCSI monitoring and trial data, PSDCHE monitoring and trial data, ERYSGR monitoring and trial data and/or PUCCRT monitoring and trial data.

The sustainability potential data may comprise immutable field data, field data recorded once per season and/or daily updated field data.

The sustainability potential data may indicate how good the actual conditions of a field are adapted for sustainable treatment. A high value may be reached when biological factors may be detectable on the field. But also, if a field is not adapted for high yield.

The immutable field data may comprise water body distance.

The field data recorded once per season for determining the sustainability potential data may comprise power zones analysis and soil samples.

The daily updated field data for determining sustainability potential data may comprise relative biomass map analysis and a heterogeneity index.

The sustainability potential data may also comprise agricultural input data recorded once per season, e.g., crop protection history and daily updated organism data like presence of beneficial insects, presence of flowering plants, presence of field margins and/or presence of bee houses.

FIG. 2 FIG. 2 illustrates an embodiment of the data flow of the computer-implemented method of the present invention.

In a first data flow section, which corresponds to the steps (S10) to (S50) of the computer-implemented method of the present invention, data sources 101 are made available, wherein the data sources can be for example a user device 103, database 105 and/or sensor 107. The term “user input device” is understood to be a computer, a smartphone, a tablet, a smartwatch, a monitor, a data storage device, or any other device, by which a user, including humans and robots, can input or transfer data to the field management system 112. The term “input database” is understood to be any organized collection of data, which can be stored and accessed electronically from a computer system, and from which data can be inputted or transferred to the field management system 112. The term “sensor” is understood to be any kind of physical or virtual device, module or machine capable of detecting or receiving real-world information and sending this real-world information to another system, including temperature sensor, humidity sensor, moisture sensor, pH sensor, pressure sensor, soil sensor, crop sensor, water sensor, and cameras.

In a further data flow section, data which originated from one of the data sources 101 are optionally preprocessed in the data preprocessing section 110, wherein such data preprocessing may include data calibration, data transformation (e.g., into a different format), data correction, data validation, and data verification.

In a further data flow section, the data which originated from one of the data sources 101 and which has been optionally preprocessed in the data preprocessing section 110 are inputted into the field management system 112, for example as crop data 122, as field data 124, as organism data 126, agricultural inputs data 128, or as field potential data 130.

In a further data flow section, which corresponds to the (step 3) of the computer-implemented method of the present invention, the above mentioned data are processed by the field management system in the data processing section 120 using for example one or more crop-related models 142, one or more field-related models 144, one or more organism-related models 146, one or more agronomic recommendation models 148, one or more field potential matching models 150, or a combination of such models. Crop-related model 142 is an algorithm which is capable of determining, predicting and/or simulating crop species, crop phenology, crop growth, crop development and other crop related properties based on specific input data. Field-related model 144 is an algorithm which is capable of determining, predicting and/or simulating soil properties of a field, weather parameters (such as temperature, precipitation, moisture, humidity, sunshine, or wind speed) or other field related properties based on specific input data. Organism-related model 146 is an algorithm which is capable of determining, predicting and/or simulating the presence or distribution of harmful or beneficial organisms in the agricultural field. Agronomic recommendation model 148 is an algorithm which is capable of determining one or more methods, products (particularly seeds or seedlings), dose rates (particularly seeding rates), time windows, or other treatment parameters for achieving a specific real-world agronomic objective based on specific input data. Field potential matching model 150 is an algorithm which is capable of determining the field potential matching indicator for each treatment schedule, based on the determined crop yield and/or environmental impact of each treatment schedule. Within the data processing section 120, the output of one of the above-mentioned model may also be directly used as input of another of the above mentioned models. Within the data processing section 120, at least two, preferably at least three of the above-mentioned models may also be run either in a parallel arrangement or in a sequential arrangement or in a combination of parallel and sequential arrangement.

In a further data flow section, which corresponds to the (step S100) of the computer-implemented method of the present invention, the final outputs of the model(s) in the data processing section 120 are transferred from the field management system to the data output layer 160 and for ex-ample outputted on a user device 162, in an output database 164 or as a control file 166. The term “user output device” is understood to be a computer, a smartphone, a tablet, a smartwatch, a monitor, a data storage device, or any other device, by which a user, including humans and robots, can receive data from the field management system 112. The term “output database” is understood to be any organized collection of data, which can be stored and accessed electronically from a computer system, and which can receive data which is outputted or transferred from the field management system 112. The term “control file” is understood to be any binary file, data, signal, identifier, code, image, or any other machine-readable or machine-detectable element useful for controlling a machine or device, for example an agricultural treatment device.

FIG. 3

FIG. 3 schematically illustrates a treatment management system 500. The treatment schedules determined by the computer-implemented method of the present invention will be outputted or further processed as a control file for an agricultural equipment embedded in the treatment management system 500, wherein the agricultural equipment is preferably a movable agricultural equipment such as a seed drill or planter, a fertilizing equipment, a conventional sprayer, a smart sprayer, an autonomous application robot or an unmanned aerial vehicle. The treatment management system 500 may comprise a movable agricultural equipment 510, a data management system 520, a field management system 112, and a client computer 540. The movable agricultural equipment 510 may also be e.g., ground robots with variable-rate applicators, or other variable-rate applicators for applying seed or crop protection products to the field 502.

In the example of FIG. 3, the movable agricultural equipment 510 is embodied as smart farming machinery. The smart farming machinery 510 may be a smart seed drill or planter, a fertilizing equipment, a smart sprayer, an autonomous application robot or an unmanned aerial vehicle and includes a connectivity system 512. The connectivity system 512 may be configured to communicatively couple the smart farming machinery 510 to the distributed computing environment. It may be configured to provide data collected on the smart farming machinery 510 to the data management system 520, the field management system 112, and/or the client computer 540 of the distributed computing environment.

The data management system 520 may be configured to send data to the smart farming machinery 510 or to receive data from the smart farming machinery 510. For instance, as detected maps or as applied maps comprising data recorded during application on the field 502 may be sent from the smart farming machinery 510 to the data management system 520. For instance, the data management system 520 may comprise georeferenced data of different fields and the associated treatment map(s).

The field management system 520 may be configured to provide a control protocol, an activation code or a decision logic to the smart farming machinery 510 or to receive data from the smart farming machinery 510. Such data may also be received through the data management system 520.

The field computer 540 may be configured to receive a user input and to provide a field identifier and an optional treatment specifier to the field management system 112. Alternatively, the field identifier may be provided by the movable agricultural equipment 510. Alternatively, the optional treatment specifier may be determined using e.g., growth stage models, weather modelling, neighbouring field incidences, etc. The field management system 112 may search the corresponding agricultural field and the associated treatment map(s) in the data management system 520 based on the field identifier and the optional treatment specifier. The field computer 540 may be further configured to receive client data from the field management system 112 and/or the smart farming machinery 510. Such client data may include for instance application schedule to be conducted on certain fields with the smart farming machinery 510 or field analysis data to provide insights into the health state of certain fields.

The treatment device 510, the data management system 520, the field management system 112, and the client computer 540 may be associated with a network. For example, the network may be the internet. The network may alternatively be any other type and number of networks.

For example, the network may be implemented by several local area networks connected to a wide area network. The network may comprise any combination of wired networks, wireless networks, wide area networks, local area networks, etc.

The data processing system of the present invention may be embodied as, or in, or as part of the field management system 112 to perform the above-described method to provide a control data to the smart farming machinery 510. For example, the field management system 112 may receive the agricultural equipment configuration data from movable agricultural equipment 510 via the connectivity system 512. The field management system 112 may receive geo-dependent environmental data (e.g., temperature, moisture, humidity, and/or wind speed) form one or more sensors installed on the movable agricultural equipment 510 to monitor environmental data. Alternatively or additionally, the field management system 112 may receive geo-dependent environmental data from weather services.

What is claimed is:

1. A method comprising:
providing crop data relating to at least one crop grown or planned to be grown in an agricultural field;
providing field data relating to one or more of one or more field conditions, one or more soil conditions, one or more weather conditions, or one or more environmental conditions in the agricultural field;
providing organism data relating to one or more of an actual or expected presence of an organism in the agricultural field relating to an actual or expected presence of health deficiencies of the organism;
providing agricultural inputs data relating to agricultural inputs usable for treating the agricultural field, wherein the agricultural inputs comprise at least one of the following inputs: seeds, irrigation water, fertilizer, chemical crop protection products, biological crop protection products, physical-mechanical crop protection products, agricultural equipment, or hours of manual work;
providing field potential data relating to a potential associated with treatment of the agricultural field;
determining, by a processing device, a set of treatment schedules for treating the agricultural field, wherein the set of treatment schedules comprises at least two treatment schedules, and wherein the set of treatment schedules comprises an indication to treat the agricultural field or to leave the agricultural field untreated;
determining a crop yield and an environmental impact associated with each treatment schedule within the set of treatment schedules;
based on the field potential data, determining a field potential matching indicator for each treatment schedule within the set of treatment schedules using a matching model, wherein the matching model is at least dependent on at least one of the determined crop yield or the environmental impact associated with each treatment schedule;
selecting at least one treatment schedule based on the field potential matching indicator; and
based on the selected treatment schedule, outputting a control file usable for controlling an agricultural equipment to treat the agricultural field;
wherein the field potential data relates to a potential of generating at least one of a high crop yield or a low environmental impact.

2. The method of claim 1, wherein a minimum threshold for the field potential matching indicator is predefined.

3. The method of claim 1, wherein the organism is a harmful organism comprising one or more of weeds, fungi, viruses, bacteria, insects, arachnids, nematodes, mollusks, or rodents.

4. The method of claim 1, wherein the organism is a beneficial organism comprising one or more of beneficial plants, beneficial weeds, beneficial viruses, beneficial bacteria, beneficial insects, pollinators, beneficial arachnids, beneficial nematodes, beneficial mollusks, or protozoa.

5. The method of claim 1, wherein the field data comprises historic treatment data relating to one or more parameters associated with historical treatments.

6. The method of claim 1, wherein the field potential data comprises one or more of in-season data or pre-season data.

7. The method of claim 1, wherein the field potential data relates to a potential to provide a habitat for one or more of to-be-protected animals, plants, or pollinators.

8. The method of claim 1, wherein the treatment schedule comprises information associated with one or more of seeding or a use of specific seeds.

9. The method of claim 1, wherein the treatment schedule comprises an application of one or more fertilizers.

10. The method of claim 1, wherein the treatment schedule comprises an application of one or more chemical crop protection products.

11. The method of claim 1, wherein the treatment schedule does not comprise an application of chemical crop protection products.

12. A system comprising:
a crop data provider configured to provide crop data relating to at least one crop grown or planned to be grown in an agricultural field;
a field data provider configured to provide field data relating to one or more of: one or more field conditions, one or more soil conditions, one or more weather conditions, or one or more environmental conditions in the agricultural field;
an organism data provider configured to provide organism data relating to one or more of an actual or expected presence of an organism in the agricultural field relating to an actual or expected presence of health deficiencies of the organism;
an agricultural inputs data provider configured to provide agricultural inputs data relating to agricultural inputs usable for treating the agricultural field, wherein the agricultural inputs comprise at least one of the following inputs: seeds, irrigation water, fertilizer, chemical crop protection products, biological crop protection products, physical-mechanical crop protection products, agricultural equipment, or hours of manual work;
a field potential data provider configured to provide field potential data relating to a potential associated with treatment of the agricultural field;
a treatment schedule generator configured to determine a set of treatment schedules for treating the agricultural field, wherein the set of treatment schedules comprises at least two treatment schedules, and wherein the set of treatment schedules comprises an indication to treat the agricultural field or to leave the agricultural field untreated;
a crop yield or environmental impact generator configured to determine a crop yield and an environmental impact associated with each treatment schedule within the set of treatment schedules;
an indicator generator configured to determine, based on the field potential data, a field potential matching indicator for each treatment schedule within the set of treatment schedules using a matching model, wherein the matching model is at least dependent on at least one of the determined crop yield or the environmental impact associated with each treatment schedule;
a treatment schedule selector configured to select at least one treatment schedule based on the field potential matching indicator; and
an outputting unit configured to output, based on the selected treatment schedule, a control file usable for controlling an agricultural equipment to treat the agricultural field, wherein the field potential data relates to a potential of generating at least one of a high crop yield or a low environmental impact.

13. A non-transitory computer-readable medium comprising instructions, which when executed by a processing device, cause the processing device to perform operations comprising:
providing crop data relating to at least one crop grown or planned to be grown in an agricultural field;
providing field data relating to one or more of: one or more field conditions, one or more soil conditions, one or more weather conditions, or one or more environmental conditions in the agricultural field;
providing organism data relating to one or more of an actual or expected presence of an organism in the agricultural field relating to an actual or expected presence of health deficiencies of the organism;
providing agricultural inputs data relating to agricultural inputs usable for treating the agricultural field, wherein the agricultural inputs comprise at least one of the following inputs: seeds, irrigation water, fertilizer, chemical crop protection products, biological crop protection products, physical-mechanical crop protection products, agricultural equipment, or hours of manual work;
providing field potential data relating to a potential associated with treatment of the agricultural field;
determining a set of treatment schedules for treating the agricultural field, wherein the set of treatment schedules comprises at least two treatment schedules, and wherein the set of treatment schedules comprises an indication to treat the agricultural field or to leave the agricultural field untreated;
determining a crop yield and an environmental impact associated with each treatment schedule within the set of treatment schedules;
determining, based on the field potential data, a field potential matching indicator for each treatment schedule within the set of treatment schedules using a matching model, wherein the matching model is at least dependent on at least one of the determined crop yield or the environmental impact associated with each treatment schedule;
selecting at least one treatment schedule based on the field potential matching indicator; and
outputting, based on the selected treatment schedule, a control file usable for controlling an agricultural equipment to treat the agricultural field, wherein the field potential data relates to a potential of generating at least one of a high crop yield or a low environmental impact.

14. The non-transitory computer-readable storage medium of claim 13, wherein the organism is a harmful organism comprising one or more of weeds, fungi, viruses, bacteria, insects, arachnids, nematodes, mollusks, or rodents.

15. The non-transitory computer-readable storage medium of claim 13, wherein the organism is a beneficial organism comprising one or more of beneficial plants, beneficial weeds, beneficial viruses, beneficial bacteria, beneficial insects, pollinators, beneficial arachnids, beneficial nematodes, beneficial mollusks, or protozoa.
